(19) United States
(12) Patent Application Publication
(10) Pub. No.: US 2013/0258205 A1
(43) Pub. Date: Oct. 3, 2013

(54) TELEVISION RECEIVER AND ELECTRONIC APPARATUS

(71) Applicant: KABUSHIKI KAISHA TOSHIBA, Tokyo (JP)

(72) Inventors: Hirokazu KAWASAKI, Tokyo (JP); Minoru ENOMOTO, Tokyo (JP)

(73) Assignee: KABUSHIKI KAISHA TOSHIBA, Tokyo (JP)

(21) Appl. No.: 13/729,481

(22) Filed: Dec. 28, 2012

(30) Foreign Application Priority Data
Mar. 30, 2012 (JP) 2012-082525

(51) Int. Cl. H04N 5/44; H05K 5/02

(52) U.S. Cl. CPC H04N 5/44; H05K 5/0247
USPC 348/725; 361/679.01

(57) ABSTRACT

According to one embodiment, an electronic apparatus includes: a housing comprising a first end and a second end on a side opposite to the first end; a first connector configured to be positioned closer to the first end than to the second end between the first end and the second end, and to be attached with an external device in a detachable manner; and a second connector configured to be positioned closer to the second end than to the first end between the first end and the second end, and to be attached with a wireless communication device in a detachable manner.

### CROSS-REFERENCE TO RELATED APPLICATIONS

This application is based upon and claims the benefit of priority from Japanese Patent Application No. 2012-082525, filed on Mar. 30, 2012, the entire contents of which are incorporated herein by reference.

### FIELD

### Background

Conventionally widely known are television receivers comprising a connector to which a wireless communication device is attached.

Such television receivers are required to suppress an influence exerted by noise from other components on wireless communications performed by a wireless communication device, for example.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary front view of a television receiver according to a first embodiment;

FIG. 2 is an exemplary perspective view of the television receiver in the embodiment viewed from the front;

FIG. 3 is an exemplary back view of the television receiver in the embodiment;

FIG. 4 is an exemplary side view of the television receiver in the embodiment, and illustrates a state in which a support is unfolded;

FIG. 5 is an exemplary side view of the television receiver in the embodiment, and illustrates a state in which the support is folded;

FIG. 6 is an exemplary perspective view of a part including a first support of the television receiver in the embodiment viewed from the front;

FIG. 7 is an exemplary perspective view of a part including the first support of the television receiver in the embodiment viewed from the back and the bottom;

FIG. 8 is an exemplary perspective view of an internal structure of the first support of the television receiver in the embodiment;

FIG. 9 is an exemplary exploded perspective view of a part including the first support of the television receiver in the embodiment viewed from the back and the bottom;

FIG. 10 is an exemplary perspective view of a part including a second support of the television receiver in the embodiment viewed from the back and the bottom;

FIG. 11 is an exemplary front view of apart of the television receiver in the embodiment;

FIG. 12 is an exemplary back view of the inside of a housing of the television receiver in the embodiment;

FIG. 13 is another exemplary back view of the inside of the housing of the television receiver in the embodiment with a cover removed;

FIG. 14 is an exemplary back view of a part in the housing of the television receiver in the embodiment;

FIG. 15 is an exemplary view on arrow XV in FIG. 14;

FIG. 16 is an exemplary back view of a part of the housing of the television receiver in the embodiment;

FIG. 17 is an exemplary perspective view of a lid of the television receiver in the embodiment viewed from the front;

FIG. 18 is an exemplary perspective view illustrating a state in which a lid for a part provided with a housing portion in the housing of the television receiver in the embodiment is removed;

FIG. 19 is an exemplary perspective view of a battery used in the television receiver in the embodiment;

FIG. 20 is an exemplary exploded perspective view of the part provided with the housing portion in the housing, the battery, and the lid of the television receiver in the embodiment;

FIG. 21 is an exemplary perspective view along a section XXI-XXI in FIG. 3; and

FIG. 22 is an exemplary sectional view schematically illustrating a state in which the battery is housed in the housing portion in the housing of the television receiver in the embodiment.

### DETAILED DESCRIPTION

In general, according to one embodiment, a television receiver comprises: a display device comprising a screen; a cover configured to cover at least a side of the display device opposite to the screen; a mask member configured to cover a periphery of the screen from a side opposite to the cover; a middle frame member comprising a first end and a second end, the display device configured to be positioned between the first end and the second end, the middle frame member configured to be positioned between the mask member and the cover and to cover at least a peripheral edge of the display device; two first supports, each of the two first supports comprising a protruding portion integral with the middle frame member and protruding from a position on a third end in a lateral direction of the screen, and closer to a center portion than the first and second ends; a second support configured to protrude from the cover in a manner separated from the two first supports; a first connector configured to be positioned closer to the first end between the first end and the second end, and to be attached with an external device in a detachable manner; and a second connector configured to be positioned closer to the second end between the first end and the second end, and to be attached with a wireless communication device in a detachable manner.

Exemplary embodiments described below comprise components similar to each other. Therefore, in the description below, common reference numerals are assigned to similar components, and overlapping explanation thereof will be omitted. Furthermore, in the drawings, directions (an X direction, a Y direction, and a Z direction) are illustrated for convenience. The X direction is a longitudinal direction with respect to a screen 4a viewed from the front, the Y direction is a lateral direction with respect to the screen 4a viewed from the front, and the Z direction is a front-back direction (a depth direction or a thickness direction of a housing 3) with respect to the screen 4a viewed from the front. The X direction, the Y direction, and the Z direction are orthogonal to one another.

In the embodiments below, an electronic apparatus is embodied as a television receiver or a personal computer, for example. However, the electronic apparatus according to the present embodiment is not limited thereto. The electronic apparatus according to the present embodiment can be embodied as various types of electronic apparatuses, such as a smartphone, a smartbook, a mobile phone, a personal digital assistant (PDA), a video display, and a video phone.

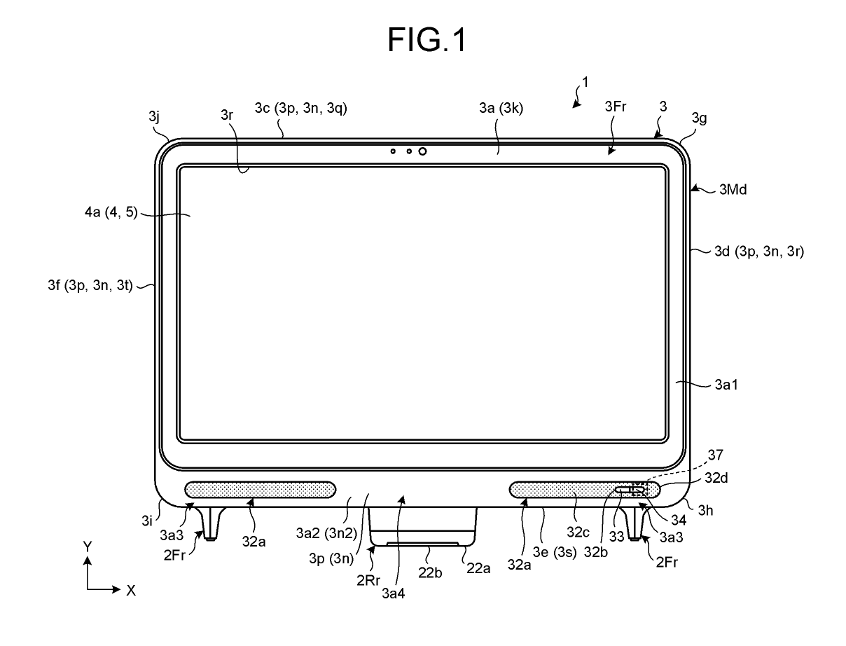

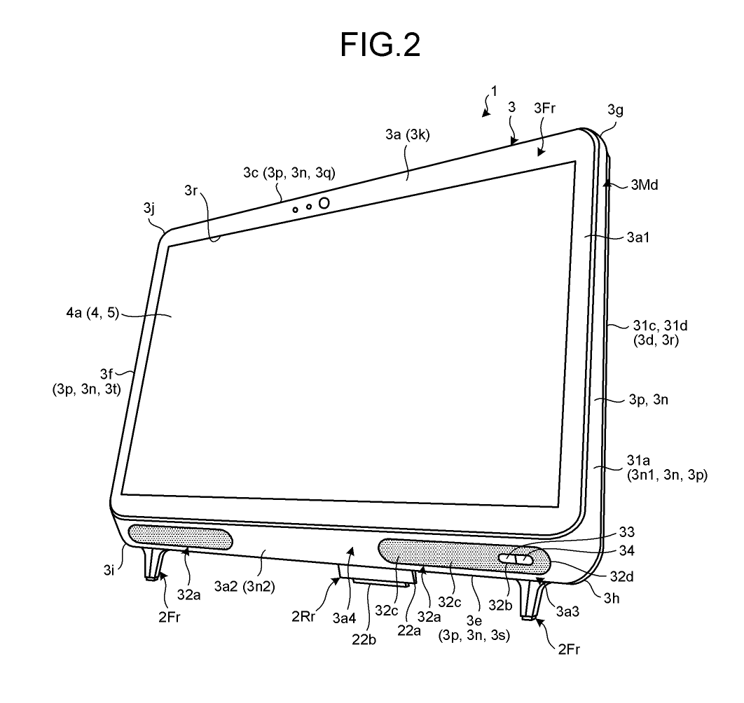

A television receiver 1 that is an example of an electronic apparatus according to an embodiment comprises supports 2Fr and 2Rr (stand parts, bases, or stands) and the housing 3 as illustrated in FIGS. 1 to 5. The supports 2Fr and 2Rr are placed on a placing section (not illustrated), such as a desk, a shelf, and a rest, and support the housing 3.

As illustrated in FIG. 1, the housing 3 is formed in a square shape (a rectangular shape in the first embodiment, for example) viewed from the front. Furthermore, as illustrated in FIGS. 1 to 5, the housing 3 is formed in a flat rectangular parallelepiped shape that has a small width in the front-back direction. The housing 3 comprises a front surface 3a (a front face, a surface, a surface portion, or a front surface portion) and a rear surface 3b (a back surface, a surface, a surface portion, or a rear surface portion) opposite to the front surface 3a. The front surface 3a is an example of a first front surface. Furthermore, as illustrated in FIG. 1, the housing 3 comprises four ends 3c to 3f (sides or edges) and four corners 3g to 3j (peaks, curves, or ends) viewed from the front. The ends 3c and 3e are both ends in the lateral direction of the housing 3 and a display 4 (screen 4a), and are examples of a long side. The ends 3d and 3f are both ends in the longitudinal direction of the housing 3 and the display 4, and are examples of a short side. The housing 3 is supported by the supports 2Fr and 2Rr in a standing manner (position).

The housing 3 further comprises a wall 3k (a portion, a plate, a frame, a bezel, a front wall, a face wall, or a top wall) comprising a front surface 3a1 and a wall 3m (a portion, a plate, a rear wall, a back wall, or a bottom wall) comprising the rear surface 3b. The front surface 3a1 serves as a part of the front surface 3a of the housing 3, and is approximately parallel to the rear surface 3b. The walls 3k and 3m are in a square shape (a rectangular shape in the first embodiment, for example). Furthermore, the housing 3 comprises four walls 3n (portions, plates, side walls, end walls, standing walls, or extending portions) comprising an extending surface 3p (a peripheral surface, a surface, or a surface portion) extending between the wall 3k and the wall 3m. At least a part of the extending surface 3p serves as a side surface of the housing 3. The wall 3k has an opening 3r in a square shape (a rectangular shape in the first embodiment, for example). In other words, the front surface 3a has the opening 3r. The opening 3r is an example of a first opening.

Furthermore, the housing 3 can be configured by combining a plurality of components (divided parts or members). The housing 3, for example, comprises a first member 3Rr (a first portion, a rear side member, abase, a bottom, aback cover, a cover, a housing, a first housing component, a covering, an outer wall, a reinforcing portion, or a supporting portion) including at least the wall 3m, a second member 3Md (a second portion, a middle member, a frame, a middle frame, a middle cover, a middle frame member, a housing, a second housing component, a reinforcing portion, a mounting portion, a supporting portion, or a support) including at least the wall 3n, and a third member 3Fr (a third portion, a front side member, a bezel, a front cover, a mask member, a housing, a third housing component, a covering, a cover, an outer wall, a reinforcing portion, or a supporting portion) including at least the wall 3k. The housing 3 can be made of a synthetic resin material and a metal material, for example. The second member 3Md has higher rigidity than that of the third member 3Fr, and has a larger outer edge than that of the third member 3Fr.

In the first embodiment, for example, the wall 3k of the third member 3Fr is formed in a square (e.g., rectangular) frame and plate shape, and covers a peripheral edge (an outer periphery) of the display device 4 as illustrated in FIG. 1. The peripheral edge of the display device 4 includes long sides and short sides of the display device 4. The peripheral edge of the display device 4 is in a square shape viewed from the back. The housing 3 at the peripheral edge of the display device 4 houses the display device 4 (a display module, a display, or a panel). The screen 4a of the display device 4 arranged on the front surface 3a side is exposed forward (outside) of the housing 3 through the opening 3r. A user can view the screen 4a from the front side through the opening 3r. In other words, the screen 4a of the display device 4 is exposed by the opening 3r. The display device 4 is formed in a square shape (a rectangular shape in the first embodiment, for example) viewed from the front. Furthermore, the display device 4 is formed in a flat rectangular parallelepiped shape that has a small width in the front-back direction. The display device 4 is a liquid crystal display (LCD) or an organic electro-luminescent display (OELD), for example. Furthermore, in the first embodiment, the display device 4 is attached to the second member 3Md, for example. To attach the display device 4 to the second member 3Md, for example, a fixture (e.g., a screw) and a bracket (a metal fitting) can be used (neither of which is illustrated).

Furthermore, the front side (face side or wall 3k side) of the display 4 is provided with an input operation panel 5 (e.g., a touch panel, a touch sensor, and an operation surface) that is transparent and is formed in a relatively thin square shape (a rectangular shape in the first embodiment, for example). The input operation panel 5 covers the screen 4a. An operator (e.g., a user) uses his/her finger or a stylus to perform an operation, such as a touch, a press, a slide, and a motion of the finger or the stylus in the vicinity of the input operation panel 5, with respect to the input operation panel 5, thereby performing input processing, for example. Furthermore, light output from the screen 4a of the display 4 passes through the input operation panel 5, and is output forward (outside) of the housing 3 through the opening 3r of the wall 3k. The input operation panel 5 is an example of an input module.

In the first embodiment, for example, the second member 3Md is formed in a square frame shape (a loop shape) viewed from the front as illustrated in FIG. 1. The second member 3Md comprises four ends 3q to 3t (sides or edges) viewed from the front. The ends 3q to 3t are material portions of the second member 3Md. The ends 3q and 3s are both ends in the lateral direction of the second member 3Md and the display device 4 (screen 4a), and are examples of the long side. The ends 3q and 3s extend in the longitudinal direction of the display device 4. Furthermore, the ends 3r and 3t of the second member 3Md are both ends in the longitudinal direction of the second member 3Md and the display device 4 (screen 4a), and are examples of the short side. The ends 3r and 3t extend in the lateral direction of the display device 4. Furthermore, the ends 3r and 3t are parts to which the display device 4 is attached (parts on which the display device 4 is mounted), for example. Connections (junctions) of the four ends 3q to 3t are curved. In other words, the ends 3q to 3t include the curved portions. Therefore, the ends 3d and 3f are parts to which the display device 4 is attached (parts on which the display device 4 is mounted). Connections (junctions) of the four ends 3c to 3f are curved, and the ends 3c to 3f include the curved portions. In the first embodiment, for example, the second member 3Md surrounds the third member 3Fr as illustrated in FIG. 1. At least within a range seen from the front, the third member 3Fr and the second member 3Md are different from each other in colors, degrees of luster, surface texture, smoothness, and surface roughness, for example. These differences in appearance facilitate discrimination of the third member 3Fr from the second member 3Md. Furthermore, on the upper (upper) end 3c and the side (both left and right) ends 3d and 3f, the width of the second member 3Md is smaller than that of the third member 3Fr viewed from the front.

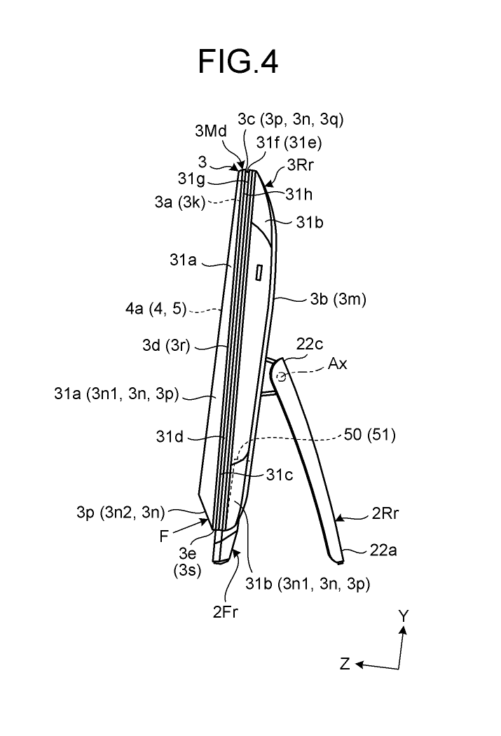

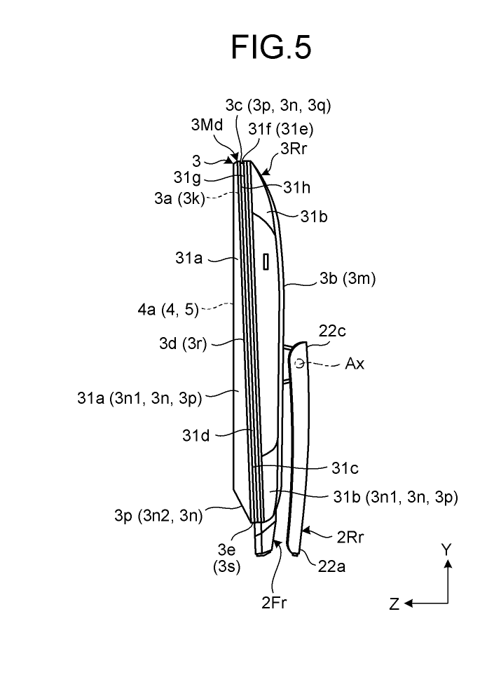

In the first embodiment, for example, a wall 3n1 (a side wall) positioned on both ends in the longitudinal direction of the display 4 among the walls 3n comprises a front portion 31a (a portion, an area, or a wall) included in the second member 3Md and a rear portion 31b (a portion, an area, or a wall) included in the first member 3Rr as illustrated in FIGS. 4 and 5. The front portion 31a is formed in a triangle shape that tapers (sharpens) upward. In other words, the width of the front portion 31a becomes narrower (smaller or thinner) gradually from the end 3e side (one end side or the lower side) to the end 3c side (the other end side or the upper side) opposite to the end 3e in the housing 3. An edge 31c of the front portion 31a on the side opposite to the screen 4a (the rear side or the right side in FIGS. 4 and 5) is formed in a linear shape. The rear portion 31b (second wall) extends toward the center portion viewed from the front of the screen 4a while extending from an edge 31d fitting to the edge 31c to the side opposite to the screen 4a (the rear side or from the left side to the right side in FIGS. 4 and 5). In the first embodiment, for example, the wall 3m of the housing 3 bulges (curves) in a convex shape toward the rear side. Portions (edges) positioned on both ends in the longitudinal direction of the wall 3m serve as the rear portions 31b of the wall 3n1.

In the first embodiment, for example, a wall 3n2 positioned on one end side (the lower end side) in the lateral direction of the display 4 among the walls 3n serves as a part of the second member 3Md as illustrated in FIGS. 1, 2, 4, and 5. At least a part of a portion of the extending surface 3p included in the wall 3n2 serves as a front surface 3a2 (surface) of the wall 3n2. The front surface 3a2 of the wall 3n2 is a part of the front surface 3a of the housing 3, and serves as the front surface 3a of the housing 3 together with the front surface 3a1 of the wall 3k. The wall 3n2 extends from a distant side (the lower side) to a close side (the upper side) viewed from the front with respect to the screen 4a while extending from the rear side (back surface side, back side, side opposite to the screen 4a, right side in FIGS. 4 and 5) to the front side (front face side, screen 4a side, left side in FIGS. 4 and 5). In other words, (the front surface 3a2 of) the wall 3n2 is inclined with respect to a direction along the screen 4a and a normal direction of the screen 4a. The front surface 3a2 is an example of an inclined surface inclined with respect to the screen 4a.

In the first embodiment, for example, the wall 3n has a groove 31e (a grove portion or a concave portion) as illustrated in FIGS. 4 to 7. The groove 31e extends along a boundary line 31i (a boundary portion or a boundary, refer to FIG. 7) between the first member 3Rr and the second member 3Md. The groove 31e comprises a bottom surface 31f (a bottom portion, a bottom, a surface, or a portion) and a pair of facing surfaces 31g and 31h extending from the bottom surface 31f. The bottom surface 31f and one of the pair of facing surfaces 31g are provided to the first member 3Rr. The other of the pair of facing surfaces 31h is provided to the second member 3Md. The boundary line 31i (FIG. 7) is positioned in the groove 31e. In the first embodiment, for example, the boundary line 31i is positioned on a boundary (a boundary portion) between the bottom surface 31f and the facing surface 31g.

In the first embodiment, for example, the first support 2Fr is provided to the end 3e (one end, a long side portion, or a lower side portion) of the housing 3 in the lateral direction of the screen 4a, and supports the housing 3 as illustrated in FIG. 1. More specifically, two first supports 2Fr are arranged in a manner distant from each other in the longitudinal direction of the screen 4a (the extending direction of the end 3e), and protrude from the end 3e (one end, the long side portion, or the lower side portion) of the housing 3 in the lateral direction of the screen 4a to support the housing 3. The two first supports 2Fr protrude downward (in a direction opposite to the end 3c) from positions each closer to the center portion than both ends (the corners 3h and 3i) in the longitudinal direction (X direction, longitudinal direction of the screen 4a, or horizontal direction) on the end 3e (one end, the long side portion, or the lower side portion) in the lateral direction (Y direction or lateral direction of the screen 4a) of the housing 3. In the first embodiment, for example, the second support 2Rr protrudes from the first member 3Rr in a manner separated from the two first supports 2Fr as illustrated in FIGS. 1 to 5. Furthermore, the second support 2Rr protrudes from a position between the two first supports 2Fr viewed from the front with respect to the screen 4a, and supports the housing 3 together with the two first supports 2Fr at three points.

In the first embodiment, for example, the first support 2Fr protrudes in a direction along the edge 31c of the front portion 31a on the side opposite to the screen 4a (rear side or right side in FIG. 4) as illustrated in FIG. 4.

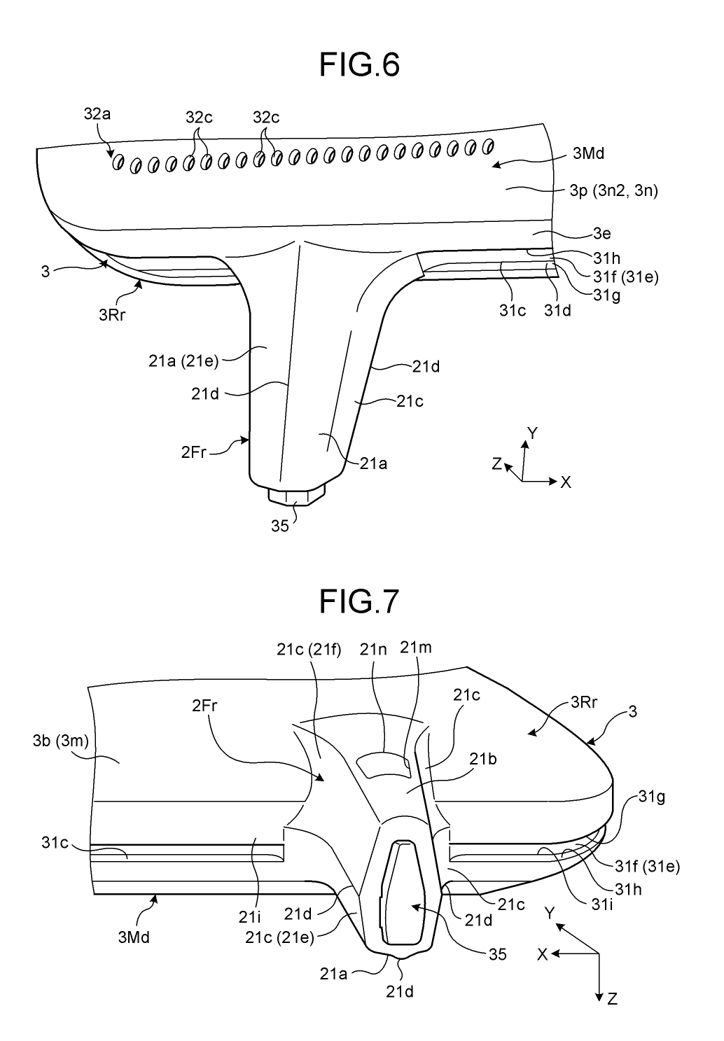

In the first embodiment, for example, the first support 2Fr is formed in a tapered shape as illustrated in FIGS. 1 to 4, and 6. In other words, the first support 2Fr tapers from the base to the tip. Furthermore, in the first embodiment, for example, a front surface 21a, a rear surface 21b, and two side surfaces 21c of the first support 2Fr bulge in a convex shape outward as is clear from FIGS. 6 and 7. Furthermore, the center portions of the front surface 21a and the two side surfaces 21c are each provided with a ridge line 21d extending between the base and the tip of the first support 2Fr. The portion of the ridge line 21d protrudes with respect to other portions on the front surface 21a and the two side surfaces 21c. The front surface 21a is an example of a second front surface.

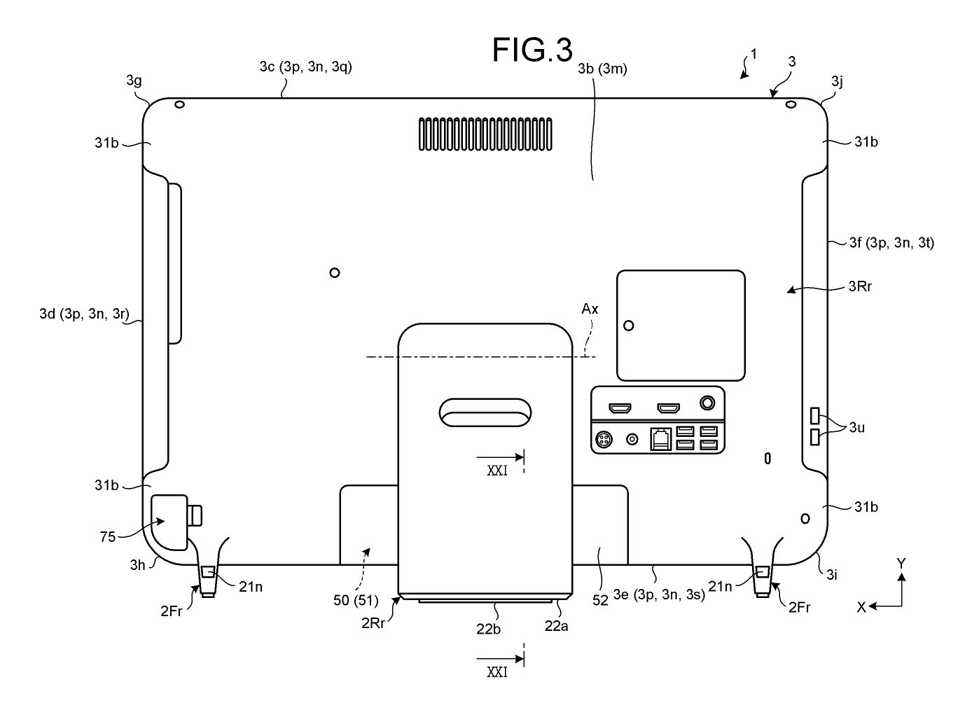

In the first embodiment, for example, the first support 2Fr comprises a protruding portion 21e (a first protruding portion) provided to the second member 3Md and a protruding portion 21f (a third protruding portion) provided to the first member 3Rr as illustrated in FIG. 9. Specifically, the protruding portion 21e protrudes downward (toward the side opposite to the end 3c) from the end 3e of the second member 3Md, and protrudes rearward (toward the side opposite to the screen 4a) with respect to the edge 31c. The protruding portion 21e comprises a first portion 21g positioned on the side opposite to the screen 4a (rear side) with respect to the edge 31c. The protruding portion 21e is in a protruding shape (a convex shape or a protuberant shape). The base (root) of the protruding portion 21e between the tip and the base is positioned near a speaker 38. The protruding portion 21f protrudes downward along the protruding portion 21e from the wall 3m (rear wall) and the wall 3n (side wall) of the first member 3Rr. The protruding portion 21f is in a protruding shape (a convex shape or a protuberant shape). The base (root) of the protruding portion 21f between the tip and the base is positioned near the speaker 38. The first member 3Rr is provided with a slit 21h into which the first portion 21g of the protruding portion 21e positioned on the rear side with respect to the edge 31c is fit. In other words, a second portion 21i of the first member 3Rr adjacent to the slit 21h is positioned on the side opposite to the tip of the first portion 21g, and comes into contact with the first portion 21g. The protruding portion 21e and the protruding portion 21f having such structures are fitted together in the front-back direction to be integrated, thereby forming the first support 2Fr. The protruding portion 21f is provided with an opening 21j, whereas the protruding portion 21e is provided with a connecting portion 21k (e.g., a male screw hole) to which a fixture (e.g., a screw, which is not illustrated) that passes through the opening 21j is connected. In other words, the protruding portion 21e and the protruding portion 21f are connected with the fixture. A concave portion 21m is provided to the edge of the opening 21j. A cap 21n (refer to FIGS. 3 and 7, for example) is fitted into the concave portion 21m to cover the concave portion 21m and the opening 21j. The cap 21n is made of a material having elasticity and flexibility, such as elastomer.

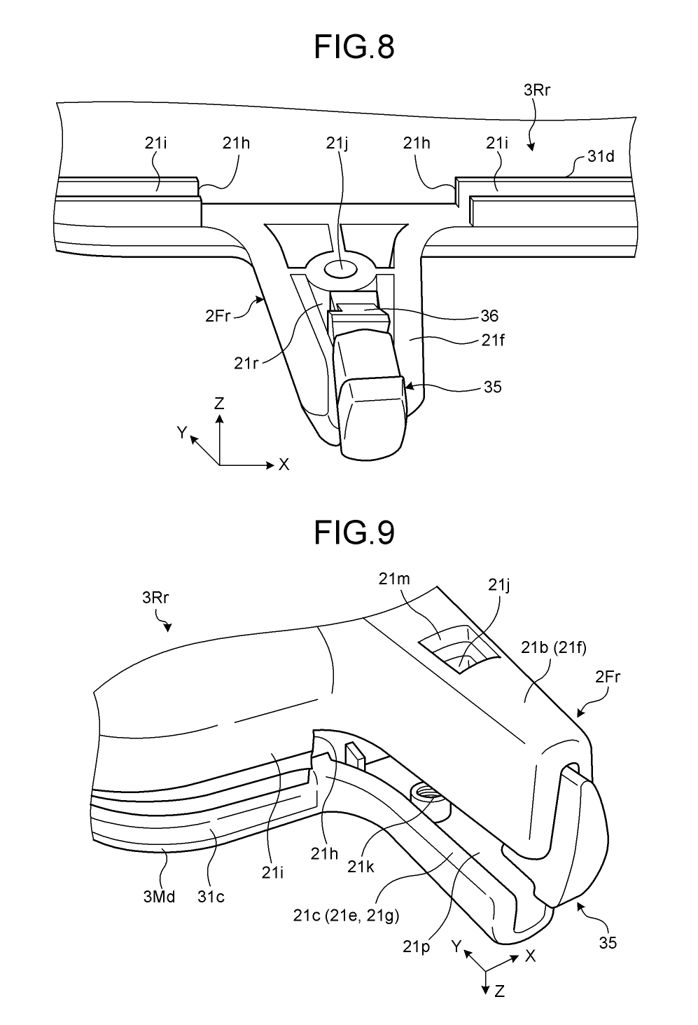

In the first embodiment, for example, an elastic member 35 having flexibility and elasticity is sandwiched between the protruding portion 21e and the protruding portion 21f as illustrated in FIGS. 8 and 9. The elastic member 35 is housed in a concave portion 21p provided to the protruding portion 21e and in a concave portion 21r provided to the protruding portion 21f. The elastic member 35 is exposed (protrudes) to the tip side (lower side) of the first support 2Fr. Furthermore, as illustrated in FIG. 8, a buffer member 36 having flexibility is arranged on the root side (upper side) of the elastic member 35. The buffer member 36 is interposed between the elastic member 35 and the first support 2Fr. The elastic member 35 is made of elastomer, for example. The buffer member 36 is made of a foamed material of a synthetic resin material, for example.

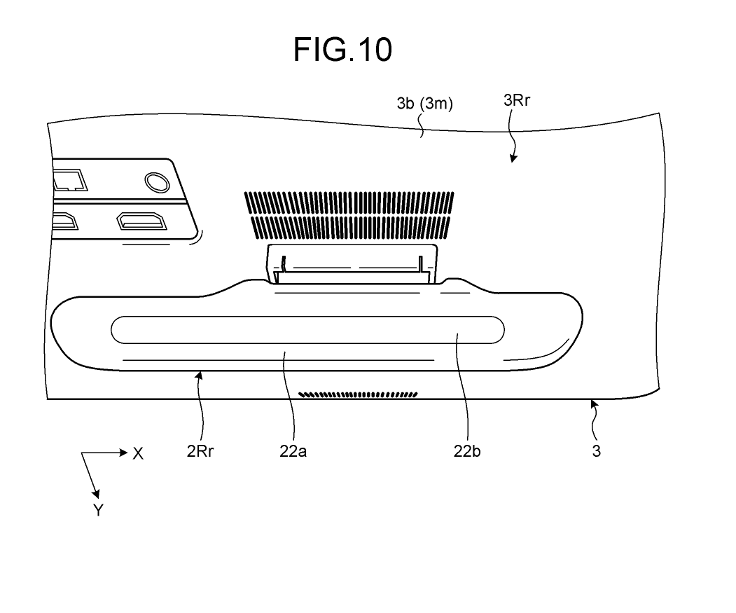

In the first embodiment, for example, the second support 2Rr has an appearance in a square shape (e.g., a rectangular shape) having the width in the longitudinal direction of the housing 3 (or the display 4) and in a plate shape as illustrated in FIGS. 1, 3, and 10. Furthermore, as illustrated in FIG. 10, an end 22a is formed in an elongated plane shape extending along the longitudinal direction of the housing 3 (or the display 4). The end 22a is provided with an elastic member 22b extending along the longitudinal direction of the end 22a. The elastic member 22b protrudes toward the tip side (lower side) from the end 22a.

In the first embodiment, for example, the second support 2Rr is supported in a rotatable manner by the wall 3m of the housing 3 as illustrated in FIGS. 4 and 5. The second support 2Rr is coupled to the wall 3m via a hinge mechanism (not illustrated) comprising two components connected in a rotatable manner about a rotation axis (Ax) illustrated in FIGS. 3 to 5. The rotation axis Ax is positioned at the center portion of the wall 3m and at an end 22c opposite to the end 22a of the second support 2Rr, and extends along the end 22a (longitudinal direction of the housing 3 and the display 4 or horizontal direction) and the rear surface 3b of the wall 3m. FIG. 4 illustrates a state in which the second support 2Rr protrudes (an unfolded state). FIG. 5 illustrates a state in which the second support 2Rr recedes (a folded state). As is clear from FIG. 4, if the second support 2Rr is unfolded, and the housing 3 is supported by the first support 2Fr and the second support 2Rr in a standing manner, the first support 2Fr extends from the rear side to the front side while extending from the upper side to the lower side, and the second support 2Rr extends from the front side to the rear side while extending from the upper side to the lower side.

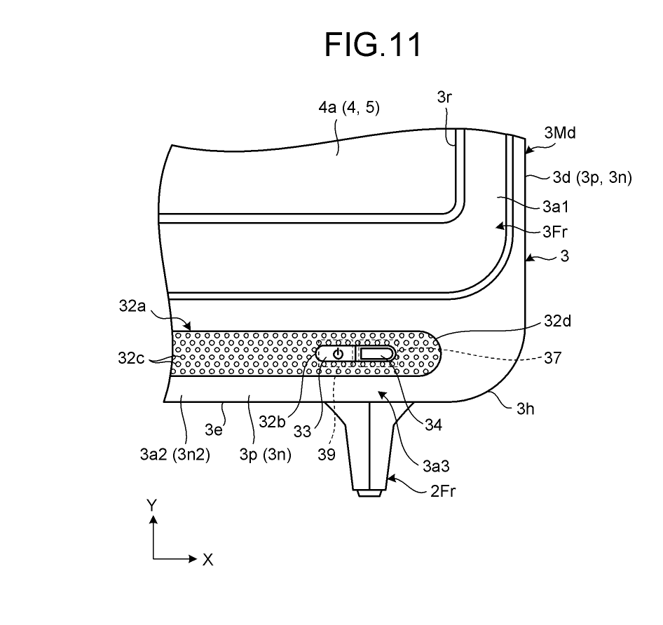

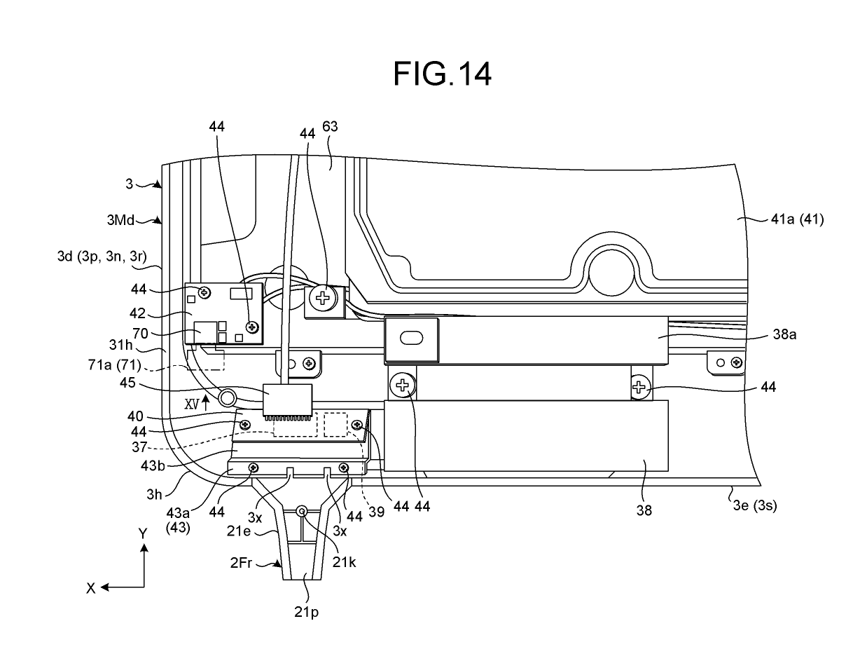

As illustrated in FIGS. 1 and 11, the wall 3n2 has openings 32a and 32b. In other words, the front surface 3a2 (inclined surface) of the wall 3n2 has the openings 32a and 32b. The opening 32b is an example of a second opening. Two openings 32a are provided in a manner distant from each other in the longitudinal direction of the screen 4a. The opening 32a has a plurality of small holes 32c (holes or through holes, refer to FIG. 6). A speaker 38 (a housed component, refer to FIG. 14) is provided to the back of the area at which the opening 32a is arranged, and speech (sound) from the speaker 38 is output through the opening 32a (small holes 32c). FIG. 14 illustrates the speaker 38 arranged in a manner corresponding to one of third openings 32a. As described above, the front surface 3a2 has the small holes 32c for outputting sound. The small hole 32c is an example of a third opening. As illustrated in FIG. 1, the openings 32a serving as areas having the small holes 32c are formed in an elongated hole shape extending along the end 3e on the left side and the right side viewed from the front. The length of the opening 32a is approximately one-third of the length of the end 3e. The opening 32b is arranged in the opening 32a serving as the area having the small holes 32c on the front surface 3a (front surface 3a1). Furthermore, the opening 32b is positioned in a manner close to an end 32d in the longitudinal direction of the screen 4a in the opening 32a (area). The opening 32b is positioned in a manner close to the end 3d between the end 3f and the end 3d.

In the first embodiment, for example, an operating element 33 of a switch 39 (a housed component) and a cover 34 of a communication module 37 (e.g., an infrared receiver or a housed component) are exposed through the opening 32b as illustrated in FIGS. 1 and 11. The cover 34 is an example of another component different from the operating element 33. The opening 32b exposes the operating element 33 and the cover 34, which is another component different from the operating element 33. The operating element 33 is an example of an operating module. The switch 39 can be configured as a so-called push-push type push-button switch that switches its ON and OFF every time the operating element 33 is pressed, for example. The operating element 33 is pressed to operate along a direction (a direction of an arrow F illustrated in FIG. 4) nearly vertical to the front surface 3a2. The switch 39 can be configured as a power switch, for example. A mark indicating the fact that the switch 39 is a power switch is provided on (the surface of) the operating element 33, for example. The operating element 33 is not limited to the switch 39, and may be provided to an adjuster that adjusts the brightness of the screen 4a, for example. The communication module 37 can be configured as a light receiver of infrared rays (infrared light), for example. The opening 32b is provided to a portion 3a3 (a first portion, a first area, or an area) positioned on the housing 3 side of one of the first supports 2Fr in the lateral direction of the screen 4a on the front surface 3a (front surface 3a2). In other words, the opening 32b is positioned above one of the first supports 2Fr, whereby the operating element 33 and the cover 34 are also positioned above one of the first supports 2Fr.

The position of the opening 32b is not limited to the position described above. For example, the opening 32b may be provided to the front surface 21a, and the operating element 33 may be exposed through the opening 32b. Alternatively, the opening 32b may be provided to a portion 3a4 positioned on the housing 3 side between the first supports 2Fr in the lateral direction of the screen 4a, and the operating element 33 may be exposed through the opening 32b. Still alternatively, the opening 32b may be positioned between a pair of first supports 2Fr arranged line-symmetrically with respect to a (virtual) center line passing through the center in the longitudinal direction of the screen 4a. In other words, the opening 32b may be positioned eccentrically with respect not to the center line of the first supports 2Fr in the longitudinal direction of the screen 4a, but to the center line of the housing 3 in the longitudinal direction of the screen 4a. As described above, the opening 32b that exposes the operating element 33 may be provided to any one of the portion 3a3 on the front surface 3a, the portion 3a4 positioned on the housing 3 side between the first supports 2Fr in the lateral direction of the screen 4a, and the front surface 21a.

In the first embodiment, for example, the operating element 33 is arranged between one of the first supports 2Fr (e.g., the first support 2Fr on the right side in FIG. 1) and the screen 4a in the lateral direction of the screen 4a as illustrated in FIGS. 1 and 11. In the first embodiment, for example, the operating element 33 is arranged ahead (on the screen 4a side) of the first support 2Fr. In the first embodiment, for example, the operating element 33 is attached to the second member 3Md. The operating element 33 is attached to the second member 3Md via a connecting member together with the switch 39, for example. In the first embodiment, for example, the operating element 33 is arranged at a position closer to the center of the opening 3r (first opening) than the cover 34 (another component) in the longitudinal direction of the screen 4a.

In the first embodiment, for example, the housing 3 houses a circuit board 40 (a board or a housed component) as illustrated in FIG. 14. The switch 39 (e.g., a power switch) provided with the operating element 33 and the communication module 37 are mounted on the front surface (a mounting surface, one surface, or a surface) of the circuit board 40. Furthermore, a connector 45 is provided to a rear surface 40a (the other surface or a surface) of the circuit board 40. The circuit board 40 is attached to the second member 3Md via a supporting member 43 (an attaching member, an intervening member, or a sheet metal member). The circuit board 40 (or the front surface and the rear surface 40a thereof) is arranged along the front surface 3a2 (inclined surface), and is inclined with respect to the screen 4a. The circuit board 40 is attached to the second member 3Md with a fixture 44 (a screw), and the supporting member 43 is also attached to the second member 3Md with the fixture 44 (screw), for example. The supporting member 43 comprises a base portion 43a and a plate portion 43b (an attaching portion) extending from the base portion 43a. The circuit board 40 is attached to the plate portion 43b. The plate portion 43b (or a part thereof) is arranged between the second member 3Md and the circuit board 40. The supporting member 43, for example, supports the operating element 33 by an engaging portion (a supporting portion or an arm, which is not illustrated) in a displaceable manner (a reciprocatable manner, a forward-and-rearward movable manner, or an operatable manner). Furthermore, the supporting member 43 engages with an engaging portion (claw) 3x provided to the second member 3Md, for example. The circuit board 40 is arranged behind (on the back surface side of) the opening 32b. The circuit board 40 is arranged above the first support 2Fr and below the display device 4. In other words, the circuit board 40 is arranged between the first support 2Fr and the display device 4. The circuit board 40 is arranged side by side with the speaker 38 in the longitudinal direction of the screen 4a. The speaker 38 is attached to the second member 3Md with the fixture 44 (screw). One end 38a (an upper end, an end, or an edge) of the speaker 38 is arranged behind the display device 4.

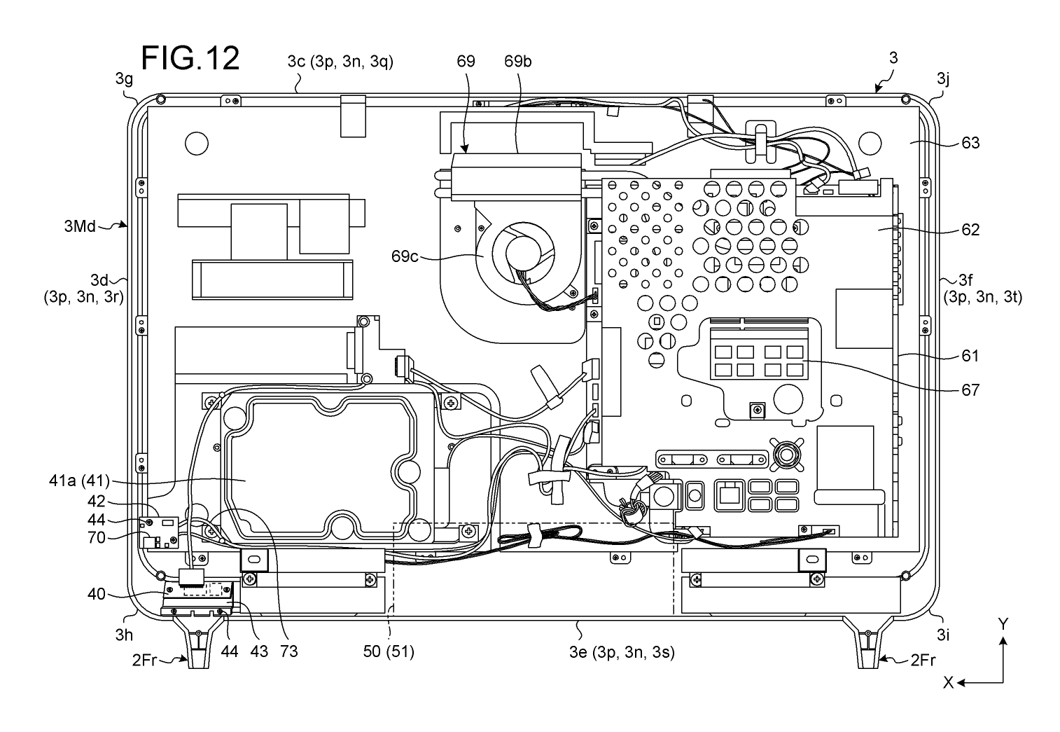

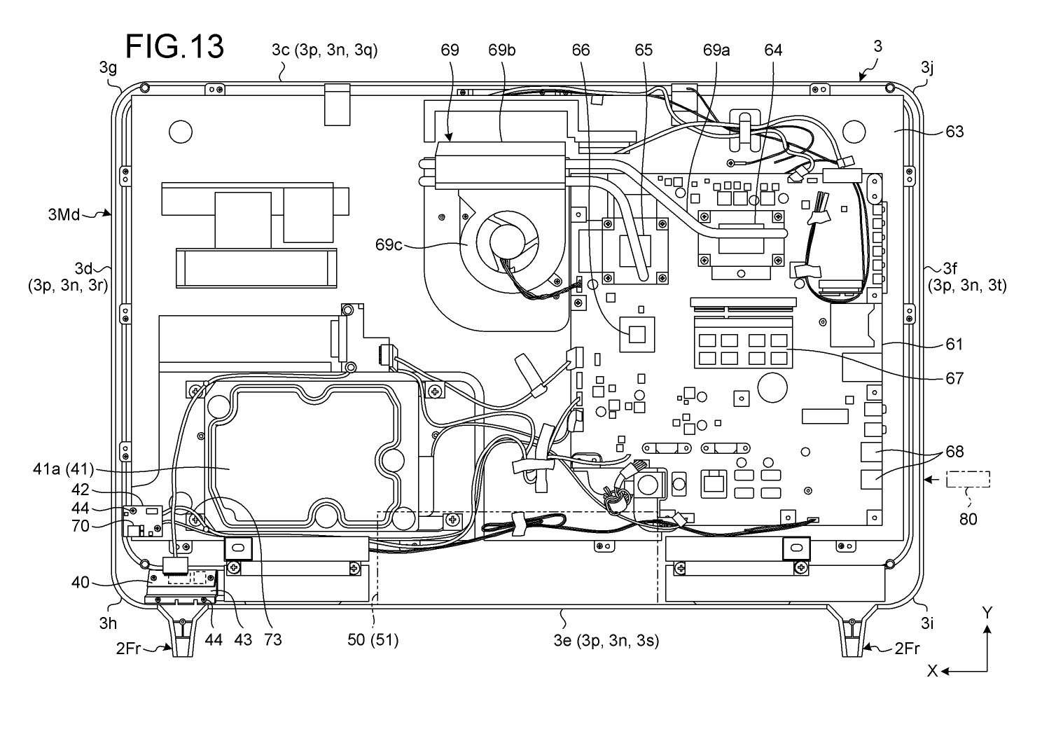

In the first embodiment, for example, the housing 3 houses a circuit board 61 (a board, a control board, a main board, or a housed component) different from the circuit board 40 on the rear side (other side, back side, wall 3m side, or side opposite to the screen 4a) of the display device 4 as illustrated in FIGS. 12 and 13. The circuit board 61 is provided in a manner overlapping with the display device 4. At least a part of the rear side (other side, back side, wall 3m side, or side opposite to the screen 4a) of the circuit board 61 is covered with a cover 62 (FIG. 12). The cover 62 is fixed to the circuit board 61 or the housing 3 with a fixture such as a screw. The circuit board 61 is provided in a manner separated from the walls 3k, 3m, 3n, and the like, that is, with a gap interposed between the circuit board 61 and each of the walls 3k, 3m, 3n, and the like. In the first embodiment, for example, the rear side (other side, back side, wall 3m side, or side opposite to the screen 4a) of the display device 4 is covered with a wall 63 (a wall member, a wall, a plate member, a shield member, or a shielding member). In other words, the wall 63 is positioned on the side opposite to the screen 4a of the display device 4. The wall 63 is positioned between the display device 4 and the first member 3Rr. The circuit board 61 is fixed to the display device 4 or the housing 3 with a fixture such as a screw. The circuit board 61 may be fixed to the display device 4 with the wall 63 interposed therebetween, for example. The circuit board 61 is positioned closer to the end 3t (end 3f) between the end 3r (end 3d) and the end 3t (end 3f). The circuit board 61 is an example of a first circuit board.

In the first embodiment, for example, a plurality of electronic components (components or elements), such as a central processing unit (CPU) 64, a graphic controller 65, a platform controller hub (PCH) 66, a storage device 67, and a connector 68 (a first connector, an electrical component, an electronic component, a connecting module, a junction module, a conducting module, a connecting component, or a component), are mounted on the circuit board 61 as illustrated in FIG. 13. The electronic components include a heating element . The CPU 64 and the graphic controller 65 serving as electronic components (heating elements) that generate a large amount of heat are provided with a cooling mechanism 69 (a heat releasing module or a heat receiving module). The cooling mechanism 69 comprises a heat pipe 69a, a radiator plate 69b, and a cooling fan 69c. The circuit board 61 and the electronic components mounted on the circuit board 61 constitute at least a part of a control circuit (not illustrated). The control circuit can comprise a video signal processing circuit, a tuner, a high-definition multimedia interface (HDMI) signal processor, an audio video (AV) input terminal, a remote-controller signal receiver, a controller, a selector, an on-screen display interface, a storage module (e.g., a read-only memory (ROM), a random access memory (RAM), and a hard disk drive (HDD)), and a speech signal processing circuit, for example. FIG. 13 and other figures illustrate an HDD 41 (an electronic component or a housed component) as an example of the storage module. The control circuit controls output of video (a moving image, a still image, or the like) by the screen 4a of the display device 4, output of speech by the speaker 38, emission of light by a light emitting diode (LED, which is not illustrated), and the like. The display device 4, the speaker 38, the LED, and the like are examples of an output module.

The connector 68 is a universal serial bus (USB) connector, for example. The connector 68 is positioned closer to the end 3t (end 3f) between the end 3r (end 3d) and the end 3t (end 3f), for example. The end 3t (end 3f) is an example of a first end, whereas the end 3r (end 3d) is an example of a second end on the side opposite to the first end. The connector 68 is arranged at a position closer to the end 3t (end 3f) between the end 3r (end 3d) and the end 3t (end 3f). The connector 68 is arranged at a position closer to one of the first supports 2Fr (one on the right side viewed from the back of the housing 3) between the two first supports 2Fr. The connector 68 is positioned near one of the first supports 2Fr (one on the right side viewed from the back of the housing 3). The connector 68 is positioned near the storage device 67. The connector 68 is positioned closer to the storage device 67 than the HDD 41. The connector 68 is exposed through an opening 3u (refer to FIG. 3) provided to the third member 3Fr. The connector 68 is used for data communications, for example. An external device 80 can be attached to and detached from the connector 68. Examples of the external device 80 include a storage device.

In the first embodiment, for example, the HDD 41 (electronic component) is housed at a portion on the rear side (other side, back side, wall 3m side, or side opposite to the screen 4a) of the display device 4 in the housing 3 as illustrated in FIGS. 13 and 14. The HDD 41 is arranged above the speaker 38 (on the end 3c side of the housing 3), and is connected (fixed) to the wall 63 with the fixture 44 (screw), for example. The HDD 41 is positioned closer to the end 3r (end 3d) between the end 3r (end 3d) and the end 3t (end 3f), for example. The HDD 41 is arranged at a position closer to the end 3r (end 3d) between the end 3r (end 3d) and the end 3t (end 3f). The HDD 41 is positioned between the connector 68 and a connector 70. The HDD 41 is positioned closer to the connector 70 between the connector 68 and the connector 70. The HDD 41 is positioned closer to the connector 70 than the connector 68. The HDD 41 is positioned near the connector 70. The HDD 41 is arranged at a position closer to the other one of the first supports 2Fr (the other one on the left side viewed from the back of the housing 3) between the two first supports 2Fr. The connector 68 is positioned near the other one of the first supports 2Fr (the other one on the left side viewed from the back of the housing 3). The HDD 41 is positioned next to (comes into contact with) one of the pair of speakers 38 (the one on the left side viewed from the back of the housing 3). The HDD 41 comprises a housing 41a in which a hard disk is housed. The housing 41a has electromagnetic shielding characteristics. The housing 41a is made of a metal, for example.

In the first embodiment, a circuit board 42 (a board or a housed component) is arranged in the vicinity of the HDD 41. The connector 70 (a second connector, an electrical component, an electronic component, a connecting module, a junction module, a conducting module, a connecting component, or a component) for a wireless communication device 71 (an electronic device, a receiver, a component, a module, an antenna, a communication module, or a device, refer to FIG. 14) is mounted on the circuit board 42. The connector 70 is an example of the second connector, and the circuit board 42 is an example of a second circuit board. The circuit board 42 is formed in a square shape viewed from the back. The circuit board 42 is smaller than the circuit board 61. The circuit board 42 and the connector 70 are housed at a position on the rear side (other side, back side, wall 3m side, or side opposite to the screen 4a) of the display device 4 in the housing 3. The circuit board 42 and the connector 70 are arranged above the circuit board 40 (on the end 3c side of the housing 3), for example. The circuit board 42 and the connector 70 are positioned closer to the end 3r (end 3d) between the end 3r (end 3d) and the end 3t (end 3f), for example. The circuit board 42 and the connector 70 are arranged at a position closer to the end 3r (end 3d) between the end 3r (end 3d) and the end 3t (end 3f). The circuit board 42 and the connector 70 are arranged at a position closer to the other one of the first supports 2Fr (the other one on the left side viewed from the back of the housing 3) between the two first supports 2Fr. The circuit board 42 and the connector 70 are arranged near the other one of the first supports 2Fr (the other one on the left side viewed from the back of the housing 3). The circuit board 42 and the connector 70 are arranged near the HDD 41. The circuit board 42 and the connector 70 are arranged closer to the HDD 41 than the storage device 67. The circuit board 42 is attached (fixed) to the wall 63 on the side of the wall 63 opposite to the display device 4 with the fixture 44 (screw), for example.

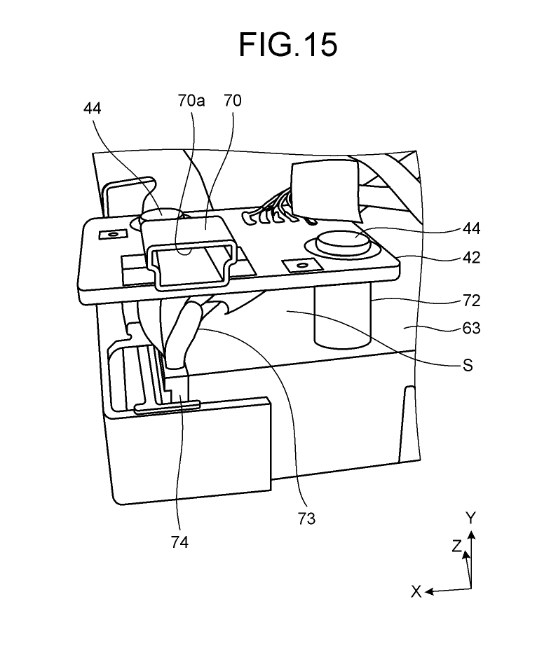

In the first embodiment, a boss 72 is provided between the circuit board 42 and the wall 63 as illustrated in FIG. 15, and the circuit board 42 is separated from the wall 63. A space S is provided between the circuit board 42 and the wall 63. A line 73 is arranged in the space S. A connector 74 is provided to an end of the line 73, and is connected to the display device 4, for example.

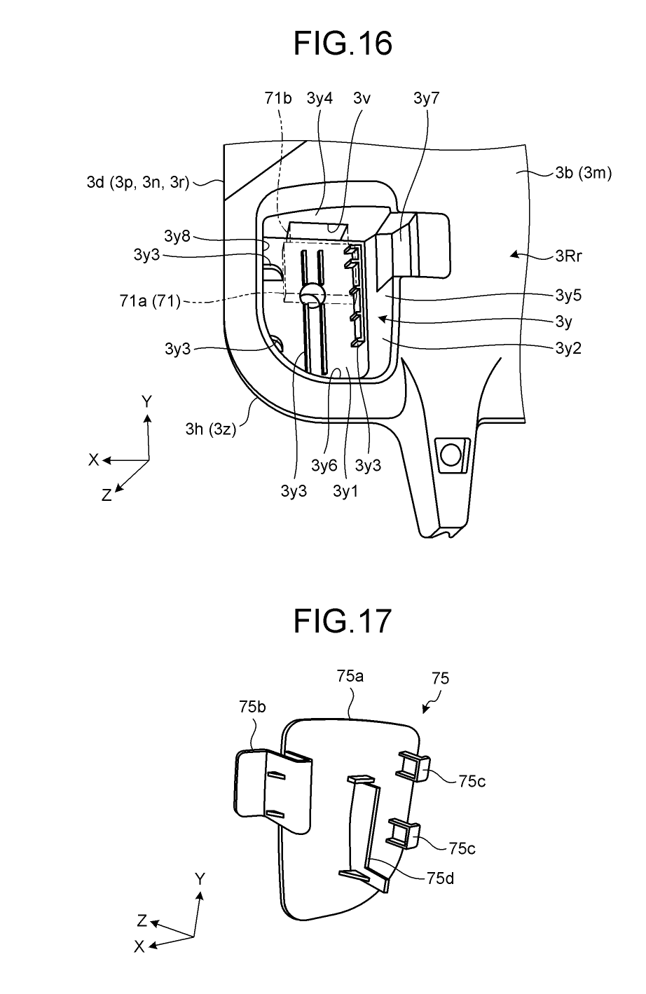

The wireless communication device 71 can be attached to and detached from the connector 70 (a dongle connector). An attachment slot 70a (an opening or an insertion slot in FIG. 15) of the connector 70 faces downward, and is exposed through an opening 3v (FIG. 16) provided to the third member 3Fr. Therefore, the wireless communication device 71 can be attached to the connector 70 from below.

The wireless communication device 71 is a dongle, for example. As illustrated in FIG. 16, the wireless communication device 71 comprises a main body 71a having an antenna built-in and an engaging portion 71b that engages with the connector 70, and performs wireless communications with a wireless communication module provided to an external device. The external device is a wireless input operating module, such as a wireless keyboard and a wireless mouse. The wireless communications are performed by using infrared rays, for example. Furthermore, as illustrated in FIG. 14, at least a part (the main body 71a) of the wireless communication device 71 attached to the connector 70 is positioned away from the display device 4 viewed in the thickness direction of the display device 4.

As illustrated in FIG. 16, the corner 3h of the housing 3, more specifically, a corner 3z of the first member 3Rr is provided with a housing portion 3y. The housing portion 3y houses the wireless communication device 71 attached to the connector 70. The housing portion 3y is formed as a recess, and an opening thereof faces the rear side. The housing portion 3y is provided with a bottom 3y1 (a wall or a front wall) and a peripheral wall 3y2 extending rearward from the bottom 3y1. The bottom 3y1 is provided with a plurality of ribs 3y3 (reinforcing portions). The peripheral wall 3y2 comprises an upper wall 3y4 (a wall or a wall portion), a side wall 3y5 (a first side wall, a wall, or a wall portion), a side wall 3y8 (a second side wall, a wall, or a wall portion), and a lower wall 3y6 (a wall or a wall portion). The upper wall 3y4 is provided with the opening 3v. The side wall 3y5 is provided with an engaging portion 3y7. The housing portion 3y is covered with a lid 75 (refer to FIGS. 3 and 17).

As illustrated in FIG. 17, the lid 75 comprises a base portion 75a in a plate shape, an engaging portion 75b provided to one end (an end or an edge) of the base portion 75a, an engaging portion 75c provided to the other end (an end or an edge) of the base portion 75a, and a rib 75d provided to the main body 71a. The lid 75 is attached to the first member 3Rr by engaging the engaging portion 75c with an engaging portion (not illustrated) provided to the side wall 3y5 of the housing portion 3y and engaging the engaging portion 75b with the engaging portion 3y7 of the housing portion 3y. By contrast, the lid 75 is removed from the first member 3Rr by removing the engaging portion 75b from the engaging portion 3y7 of the housing portion 3y and removing the engaging portion 75c from the engaging portion provided to the side wall 3y5.

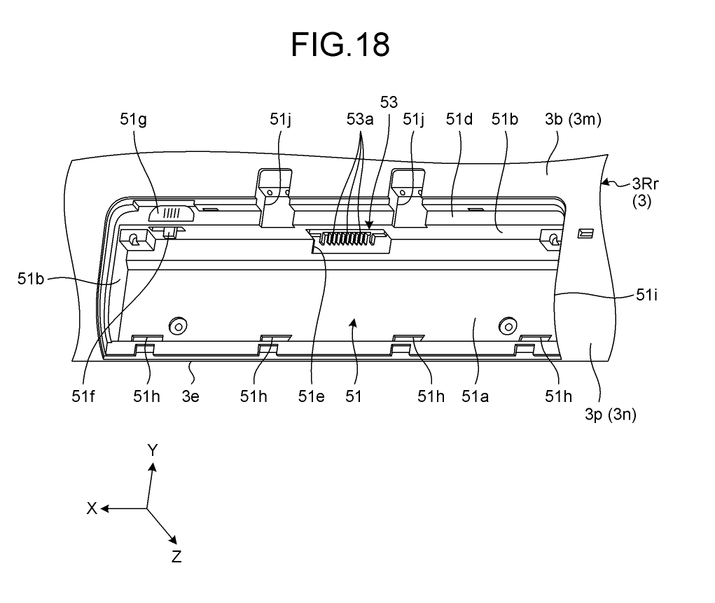

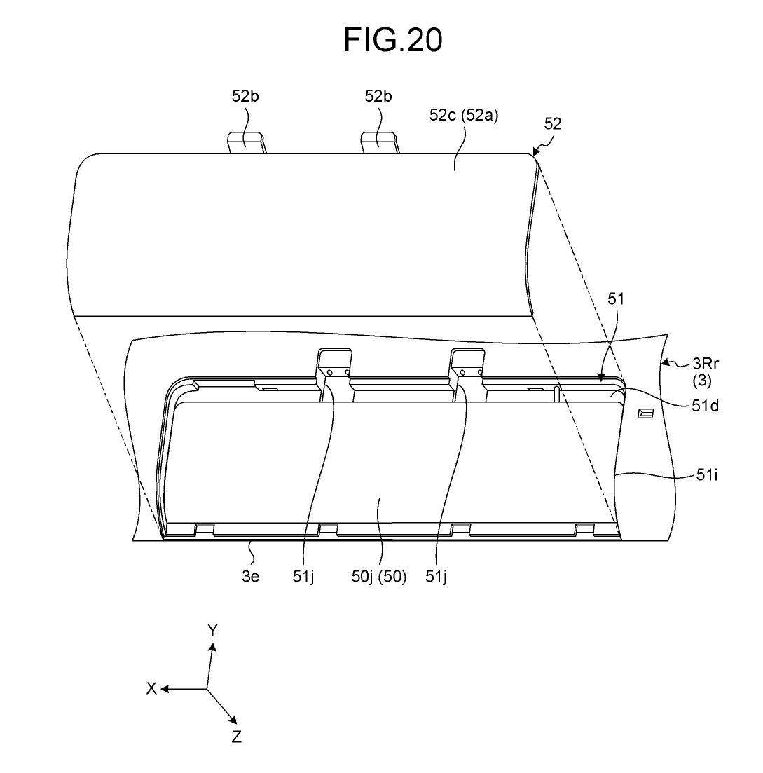

In the first embodiment, for example, the end 3e on the lower side (a support 2Fr and 2Rr side or a placing surface side) of the housing 3 is provided with a housing portion 51 for a battery 50 (an electric battery, a storage battery, an assembled battery, a battery module, a housed component, a component, a module, or a detachable component) serving as an apparatus power supply as illustrated in FIGS. 3 and 18. The housing portion 51 is covered by a lid 52 (a covering portion, a sealing portion, a cover, or a cap, refer to FIGS. 3 and 20) with the battery 50 housed therein.

In the first embodiment, for example, the housing portion 51 (battery 50) is provided between the two supports 2Fr. Furthermore, as is clear from FIG. 4, the housing portion 51 (battery 50) is provided among the three supports 2Fr and 2Rr. As described above, in the first embodiment, the housing portion 51 (battery 50) is provided between the two supports 2Fr and among the three supports 2Fr and 2Rr, for example. Therefore, according to the first embodiment, loss of balance of the housing 3 caused by providing the battery 50 having a relatively large weight to the housing 3 is likely to be suppressed, for example. In other words, the center of gravity of the television receiver 1 is positioned on the lower side, thereby making the television receiver 1 more unlikely to fall over, for example.

In the first embodiment, for example, the support 2Rr is positioned on the opposite side (rear side, back surface side, or back side) to the screen 4a with respect to the lid 52 as illustrated in FIG. 3. Therefore, according to the first embodiment, contact with the lid 52 (with an operating portion 52b thereof) made by the user is likely to be suppressed by the support 2Rr, for example. Accordingly, a false opening operation of the lid 52 is likely to be suppressed, for example.

In the first embodiment, for example, the battery 50 is positioned between the two speakers 38 on the lower side of the display device 4 as illustrated in FIGS. 12 and 13. Therefore, according to the first embodiment, by arranging the speakers 38 and the battery 50 along the end 3e, it is possible to use the space on the lower side (support 2Fr and 2Rr side) of the display device 4 in the housing 3 more efficiently, for example. Furthermore, in the first embodiment, loss of balance of the housing 3 caused by providing the speakers 38 to the housing 3 along with the battery 50 is more likely to be suppressed, for example. In other words, the center of gravity of the television receiver 1 is positioned on the lower side, thereby making the television receiver 1 more unlikely to fall over, for example. Moreover, in the first embodiment, the battery 50 is arranged at the center position (middle position) in the longitudinal direction of the end 3e, and the two speakers 38 are arranged in a manner sandwiching the battery 50, for example. Therefore, according to the first embodiment, loss of balance in the longitudinal direction (horizontal direction in FIGS. 12 and 13) of the housing 3 of the television receiver 1 is likely to be suppressed, for example.

In the first embodiment, for example, the housing portion 51 (battery 50) is positioned away from the supports 2Fr and 2Rr as is clear from FIGS. 3 and 4. Therefore, according to the first embodiment, the housing portion 51 can be formed in a simpler way, and the rigidity of the supports 2Fr and 2Rr is unlikely to be reduced compared with the case where the housing portion 51 is positioned closer to or overlapping with the supports 2Fr and 2Rr, for example.

In the first embodiment, for example, the housing portion 51 is provided to the rear surface 3b of the housing 3, and an opening thereof faces the rear side, that is, the side opposite to the screen 4a as illustrated in FIG. 3. Therefore, according to the first embodiment, the housing portion 51 and the lid 52 are unlikely to be seen from the front (front side) of the screen 4a, for example. As a result, the appearance is unlikely to be spoiled by the housing portion 51 and the lid 52, for example.

In the first embodiment, for example, the housing portion 51 is provided as a recess that extends from the wall 3m to the wall 3n of the first member 3Rr and whose opening faces the rear side (side opposite to the screen 4a) and the lower side (placing surface side, side opposite to the end 3c, or protruding direction of the supports 2Fr and 2Rr) as illustrated in FIG. 18. The housing portion 51 extends along the end 3e. The housing portion 51 mainly comprises a wall 51a (a bottom wall portion, a bottom wall, or an inner wall) and a wall 51b (a side wall portion, a peripheral wall portion, a side wall, or a peripheral wall). The wall 51a is provided in a manner approximately parallel to the screen 4a or the rear surface 3b, that is, in a manner intersecting with (perpendicular to, in the first embodiment, for example) the direction (normal direction) perpendicular to the screen 4a and along the X-Y plane on the inner side of the recess. The wall 51a is formed in a rectangular shape. The wall 51b surrounds the periphery of the wall 51a, and intersects with (is perpendicular to, in the first embodiment, for example) the wall 51a. As described above, the housing portion 51 extends from the wall 3m to the wall 3n on the end 3e, and the opening thereof faces the rear side and the lower side. Therefore, no wall 51b is provided to the lower side. Furthermore, the wall 51b on the side opposite to the end 3e in the housing portion 51 is provided with a surface 51d (a step surface, a step portion, a wall, a rebate, or a recess) positioned between the rear surface 3b and the wall 51b. As described above, in the first embodiment, the housing portion 51 is formed on the first member 3Rr (on the wall 3m and the wall 3n thereof) as a recess, for example. Therefore, the rigidity of the first member 3Rr is likely to be increased, for example.

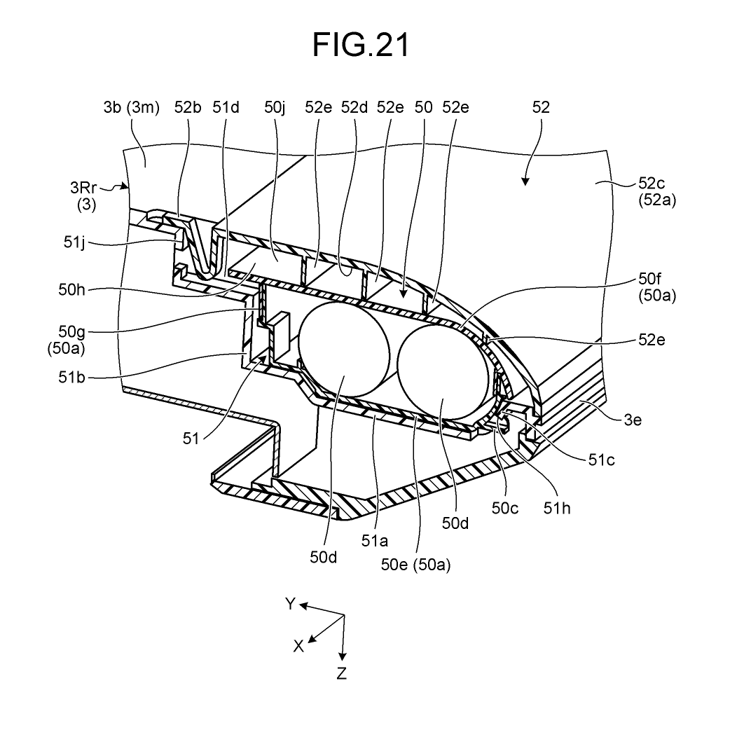

The wall 3m in the housing portion 51 (a boundary part between the wall 51a and the wall 51b) is provided with an opening 51e, and a connector module 53 is exposed through the opening 51e. The connector module 53 comprises a plurality of fins 53a (walls) provided in a manner parallel to one another. Each of the fins 53a is provided with a terminal (not illustrated) that is electrically connected to a terminal (not illustrated) of a connector module 50b of the battery 50 and that electrically connects a conductor module in the battery 50 (e.g., an electrode of a cell 50d (refer to FIG. 21)) to a conductor module in the housing 3 (e.g., the circuit board 40 (refer to FIG. 13)). Slits between the fins 53a are opened at least rearward and downward.

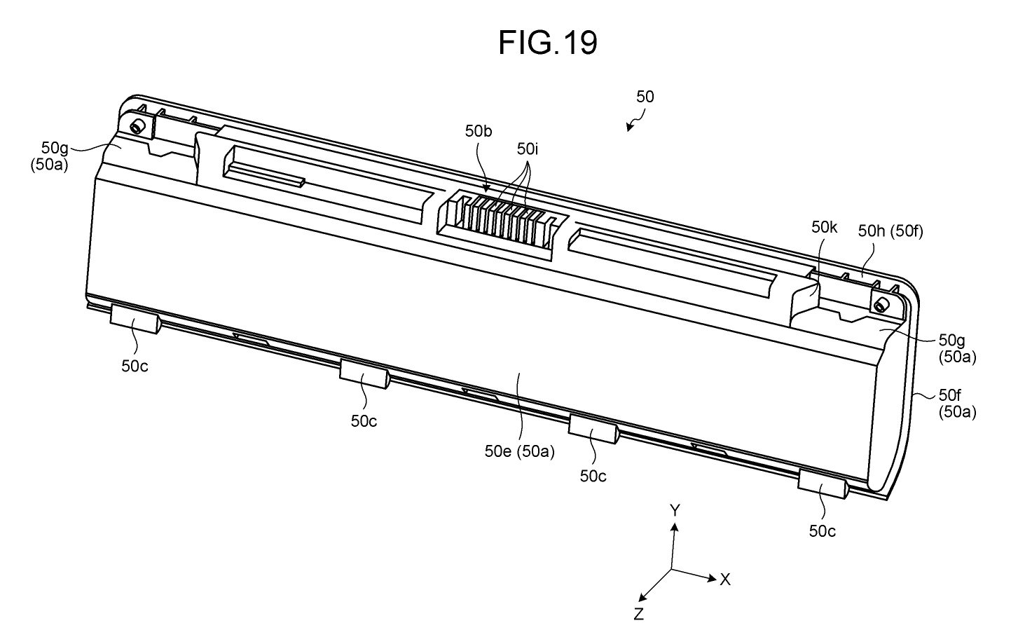

In the housing portion 51, the wall 51b supports a hook 51f in a slidable manner. The hook 51f (a hanging portion or a retaining portion) interlocks with an operating element 51g (an operating portion). By operating the operating element 51g, the user can switch the states between the state in which the battery 50 is locked by the housing 3 and the state in which the battery 50 is released. The hook 51f and the operating element 51g are biased toward one side (e.g., toward the right in FIG. 18) by a biasing member (an elastic member, e.g., a spring), which is not illustrated. In the housing portion 51, the wall 3m (wall 51a) on the end 3e side is provided with an opening 51h. The hook 51f engages with a hook portion 50k (refer to FIG. 19) provided to the battery 50, thereby preventing the battery 50 from coming off of the housing portion 51.

In the first embodiment, for example, the battery 50 has a flat and elongated appearance as illustrated in FIG. 19. The battery 50 comprises a housing 50a, the connector module 50b, a protruding portion 50c, and the cell 50d (refer to FIG. 21), for example. As illustrated in FIG. 21, the housing 50a comprises an inner wall 50e (a wall), an outer wall 50f (a wall), and an upper wall 50g (a wall). One end (an upper end in FIG. 19) in the width direction of the outer wall 50f projects outward to form a flange 50h. The connector module 50b is provided between the upper wall 50g and the flange 50h. The connector module 50b comprises a plurality of fins 50i (walls) provided in a manner parallel to one another. Each of the fins 50i is provided with the terminal (not illustrated) that is electrically connected to the terminal (not illustrated) of the connector module 53 provided to the housing 3 and that electrically connects the conductor module in the battery 50 (e.g., the electrode of the cell 50d) to the conductor module in the housing 3 (e.g., the circuit board 40 (refer to FIG. 13)). Slits between the fins 53a are opened at least forward (toward the screen 4a side) and upward (toward the side opposite to the placing surface or toward the side opposite to the protruding direction of the supports 2Fr and 2Rr) with the battery 50 attached.

In the first embodiment, for example, the lid 52 (covering portion) covers the battery 50 and the housing portion 51 with the battery 50 housed in the housing portion 51 as illustrated in FIGS. 20 and 21. The lid 52 comprises a wall 52a, the operating portion 52b, and a rib 52e (a protruding portion), for example. The wall 52a covers (seals) an opening edge 51i of the housing portion 51 to become continuous with the walls 3m and 3n. In other words, if the lid 52 is attached, an outer surface 52c (a surface or a surface portion) of the wall 52a becomes continuous with the rear surface 3b and the extending surface 3p of the walls 3m and 3n, and forms a smooth curved surface integrally with these surfaces. The operating portion 52b is inserted into an opening 51j provided to the wall 3m while being deformed elastically, and engages with a peripheral edge of the opening 51j. By deforming the operating portion 52b elastically, the user can release the engagement of the operating portion 52b with the peripheral edge of the opening 51j to remove the lid 52.

In the first embodiment, for example, an inner surface 52d (a surface or a surface portion) on the battery 50 side of the wall 52a is provided with the rib 52e (a protruding portion or a wall) protruding toward the battery 50 side as illustrated in FIG. 21. Providing the rib 52e can increase the rigidity of the lid 52. Furthermore, as is clear from FIG. 21, gaps having different intervals are provided between an outer surface 50j of the battery 50 and the inner surface 52d of the wall 52a of the lid 52. In other words, according to the first embodiment, because the lid 52 is provided, the shape of the outer wall 50f of the battery 50 need not completely conform to the shapes of the walls 3m and 3n of the housing 3, for example. Therefore, the lid 52 allows greater flexibility in designing the battery 50, for example.

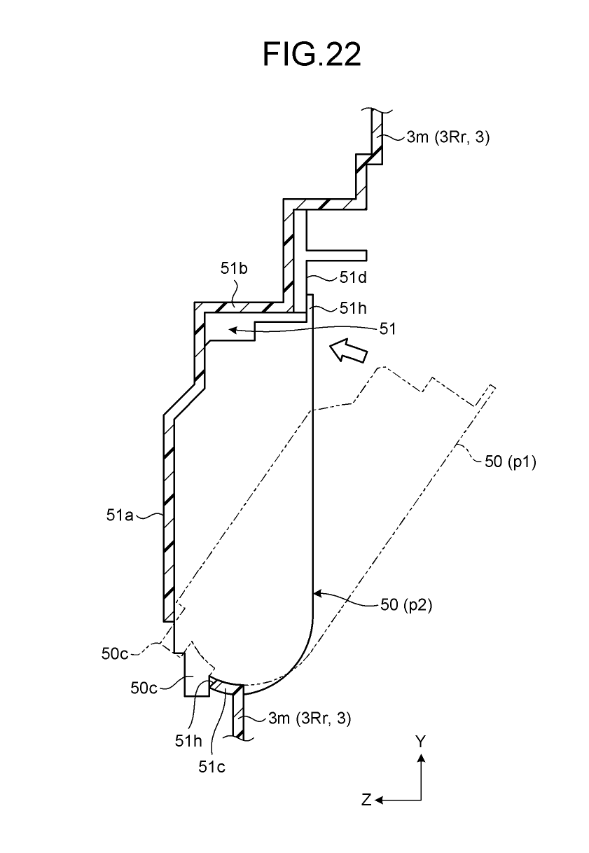

In the first embodiment, for example, to house the battery 50 in the housing portion 51, the protruding portion 50c of the battery 50 is inserted into the opening 51h, the battery 50 is rotated from a first position P1 to a second position P2 while the protruding portion 50c (a fourth supporting portion) of the battery 50 is being supported by a peripheral edge 51c (a third supporting portion) of the opening 51h, and the battery 50 is fitted into the housing portion 51 as illustrated in FIG. 22. Therefore, according to the first embodiment, the battery 50 can be housed in the housing portion 51 in a relatively simple manner, for example. The connector module 50b and the connector module 53 are provided with the fins 50i and the fins 53a, respectively, and the slits (at least in the circumferential direction of rotation of the battery 50, and slits extending along the Y-Z plane in the first embodiment, for example). The connector module 50b can be moved between the first position P1 at which the connector module 50b is separated from the connector module 53 and the second position P2 at which the connector module 50b is electrically connected to the connector module 53.

As described above, in the first embodiment, for example, the television receiver 1 comprises the two first supports 2Fr comprising the protruding portion 21e protruding from positions closer to the center portion than the ends 3d and 3f on both ends in the longitudinal direction of the screen 4a on the end 3e of the second member 3Md in the lateral direction of the screen 4a and the second support 2Rr protruding from the first member 3Rr in a manner separated from the two first supports 2Fr. Therefore, according to the first embodiment, for example, the television receiver 1 can be supported by the first supports 2Fr and the second support 2Rr in a smaller area. Accordingly, the configuration described above facilitates placing the television receiver 1 in a smaller space, for example. Furthermore, the configuration described above allows a portion including the first supports 2Fr to look slimmer or smaller than in a configuration in which supports are arranged on both ends in the longitudinal direction, for example.

In the first embodiment, for example, the connector 68 is positioned closer to the end 3t (end 3f) between the end 3r (end 3d) and the end 3t (end 3f), whereas the connector 70 is positioned closer to the end 3r (end 3d) between the end 3r (end 3d) and the end 3t (end 3f). Therefore, according to the first embodiment, because the connector 70 is distant from the connector 68, it is possible to suppress an influence exerted by noise from the connector 68 serving as another component provided to the television receiver 1 on wireless communications performed by the wireless communication device 71 attached to the connector 70, for example. Consequently, according to the first embodiment, the wireless communication device 71 can perform excellent wireless communications, for example.

In the first embodiment, for example, the circuit board 42 is attached to the wall 63 on the side of the wall 63 opposite to the display device 4. Therefore, according to the first embodiment, attachment of the circuit board 42 can be facilitated, for example.

In the first embodiment, for example, the circuit board 42 is separated from the wall 63. Therefore, according to the first embodiment, it is possible to suppress entering of noise from the display device 4 to the circuit board 42 and the wireless communication device 71, for example.

In the first embodiment, for example, at least a part (the main body 71a) of the wireless communication device 71 attached to the connector 70 is separated from the display device 4 viewed in the thickness direction of the display device 4. Therefore, according to the first embodiment, it is possible to suppress entering of noise from the display device 4 to the wireless communication device 71, for example.

In the first embodiment, for example, the corner 3z of the first member 3Rr is provided with the housing portion 3y (housing portion) that houses the wireless communication device 71 attached to the connector 70. Therefore, according to the first embodiment, attachment and removal of the wireless communication device 71 can be facilitated, for example.

In the first embodiment, for example, the HDD 41 comprising the housing 41a having electromagnetic shielding characteristics is positioned between the connector 68 and the connector 70. Therefore, according to the first embodiment, the HDD 41 prevents (restricts) noise from traveling from the connector 68 to the connector 70, whereby the wireless communication device 71 can perform excellent wireless communications, for example.

In the first embodiment, for example, the television receiver 1 comprises the battery 50 housed in an attachable and detachable manner in the housing portion 51 that is provided to the position between the two first supports 2Fr on the end 3e on the two first supports 2Fr side of the first member 3Rr and that is bored on the side opposite to the screen 4a, and the lid 52 that covers the housing portion 51. Therefore, according to the first embodiment, the shapes of the outer wall 50f and the outer surface 50j of the battery 50 need not conform to the shapes of the rear surface 3b and the extending surface 3p of the housing 3, for example. As a result, it is possible to further increase flexibility in designing the battery 50, for example. Consequently, troubles and costs of manufacturing the battery 50 can be further reduced, for example.

In the first embodiment, for example, the housing portion 51 is provided to the first member 3Rr as a recess, for example. Therefore, according to the first embodiment, the walls 3m and 3n are bent at the part to which the housing portion 51 is provided, whereby it is possible to increase the rigidity of the walls 3m and 3n and even of the housing 3, for example.

In the first embodiment, for example, the housing portion 51 (battery 50) is provided between the two supports 2Fr and among the three supports 2Fr and 2Rr, for example. Therefore, according to the first embodiment, loss of balance of the housing 3 caused by providing the battery 50 having a relatively large weight to the housing 3 is likely to be suppressed, for example. In other words, the television receiver 1 is more unlikely to fall over, for example.

Furthermore, the technological characteristics in the embodiments and the modifications can be combined appropriately or partially substituted. Moreover, the specifications (a structure, a type, a direction, a shape, a size, a length, a width, a thickness, a height, the number, an arrangement, a position, a material, and the like) of each of the configurations and the parts can be changed appropriately.

Moreover, the various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television receiver comprising:
a display device comprising a screen;
a cover configured to cover at least a side of the display device opposite to the screen;
a mask member configured to cover a periphery of the screen from a side opposite to the cover;
a middle frame member comprising a first end and a second end, the display device configured to be positioned between the first end and the second end, the middle frame member configured to be positioned between the mask member and the cover and to cover at least a peripheral edge of the display device;
two first supports, each of the two first supports comprising a protruding portion integral with the middle frame member and protruding from a position on a third end in a lateral direction of the screen, and closer to a center portion than the first and second ends;
a second support configured to protrude from the cover in a manner separated from the two first supports;
a first connector configured to be positioned closer to the first end between the first end and the second end, and to be attached with an external device in a detachable manner; and
a second connector configured to be positioned closer to the second end between the first end and the second end, and to be attached with a wireless communication device in a detachable manner.

2. The television receiver of claim 1, further comprising:
a first circuit board on which the first connector is mounted; and
a second circuit board on which the second connector is mounted.

3. The television receiver of claim 2, further comprising:
a wall configured to be positioned on a side of the display device opposite to the screen, wherein
the second circuit board is configured to be attached to the wall on a side of the wall opposite to the display device.

4. The television receiver of claim 3, wherein the second circuit board is configured to be separated from the wall.

5. The television receiver of claim 1, wherein at least a part of the wireless communication device attached to the second connector is configured to be separated from the display device viewed in a thickness direction of the display device.

6. The television receiver of claim 1, wherein a corner of the cover comprises a housing portion configured to house the wireless communication device attached to the second connector.

7. The television receiver of claim 1, further comprising an electronic component comprising a housing having electromagnetic shielding characteristics, the electronic component being positioned between the first connector and the second connector.

8. The television receiver of claim 7, wherein the electronic component is configured to be positioned closer to the second connector than to the first connector between the first connector and the second connector.

9. The television receiver of claim 1, wherein the first connector is configured to be used for data communications.

10. An electronic apparatus comprising:
a housing comprising a first end and a second end on a side opposite to the first end;
a first connector configured to be positioned closer to the first end than to the second end between the first end and the second end, and to be attached with an external device in a detachable manner; and
a second connector configured to be positioned closer to the second end than to the first end between the first end and the second end, and to be attached with a wireless communication device in a detachable manner.
